(19) United States
(12) Patent Application Publication
(10) Pub. No.: US 2003/0186511 A1
(43) Pub. Date: Oct. 2, 2003

(54) Method of forming an implantation-induced isolation

(76) Inventors: Cheng-Ta Yiu, Ilan City (TW); I-Jen Huang, Kaohsiung (TW)

Correspondence Address: FISH & RICHARDSON PC, 225 FRANKLIN ST, BOSTON, MA, 02110, US

(21) Appl. No.: 10/107,509

(22) Filed: Mar. 27, 2002

(51) Int. Cl. H01L 21/76

(52) U.S. Cl. 438/400

(57) ABSTRACT

A method of forming an implantation-induced isolation in a semiconductor substrate. First, an ion-implantation mask, such as a photoresist mask or a hard mask made of silicon nitride is defined on the semiconductor substrate to cover the active region. Second, oxygen ions are implanted into the semiconductor substrate to form an oxygen doping region for formation of the implantation-induced isolation. Third, a thermal annealing is used so that an isolating structure serving as the implantation-induced isolation is generated by reaction of the oxygen ions in the oxygen doping region with the component of the semiconductor substrate.

### BACKGROUND OF THE INVENTION

1. Field of the Invention

The present invention relates to the manufacture of semiconductor devices, more particularly to a method of forming an implantation-induced isolation.

2. Description of the Related Art

The method of local oxidation of silicon(LOCOS) to form field oxide isolation around semiconductor devices built into the surface of silicon wafers has been practiced for over twenty-five years and has been adapted to many specific applications. In the process, a non-oxidizable mask of silicon nitride is formed over a thin layer of pad oxide grown on a blank silicon wafer. The mask is patterned by well-known photolithography and the wafer is oxidized, typically in steam, at temperatures in the neighborhood of 1,000° C. The mask is patterned so that, after oxidation, mesa-like regions of silicon are surrounded by a region of silicon oxide insulation. The semiconductor devices are then formed on the silicon mesas. Over the years many problems with LOCOS have surfaced which have been addressed in a great variety of ways. Most notable are the problems which deal with the growth of oxide under the mask (birds beak) and the resultant uneven surface topology over the field oxide.

A promising replacement for LOCOS field oxide isolation has been found in trench isolation (i.e. shallow trench isolation; STI). The trenches are formed in the silicon around the semiconductor devices by reactive ion etching followed by deposition of an insulating layer and planarization of the insulating layer by chemical mechanical polishing. In addition, as the scale of the devices shrinks, the width/area of the STI at the chip surface is too large, thus using up valuable active area. Therefore, improved methods of forming isolation regions are needed for semiconductor devices that will reduce or eliminate the effects of problems associated with LOSOS and STI methods.

### SUMMARY OF THE INVENTION

In view of the above disadvantages, an object of the invention is to provide a method of forming an implantation-induced isolation without the steps of a trench etching, deposition of an insulator, and chemical mechanical polishing of the insulator. Therefore, the process complexity and manufacturing cost can be reduced.

A further object of the invention is to provide a method of forming an implantation-induced isolation which can achieve a relatively smaller dimension.

Accordingly, the above object is attained by providing a method of forming an implantation-induced isolation in a semiconductor substrate. First, an ion-implantation mask, such as a photoresist mask or a hard mask made of silicon nitride is defined on the semiconductor substrate to cover the active region. Second, oxygen ions are implanted into the semiconductor substrate to form an oxygen doping region for formation of the implantation-induced isolation. Third, a thermal annealing is used so that an isolating structure serving as the implantation-induced isolation is generated by reaction of the oxygen ions in the oxygen doping region with the component of the semiconductor substrate.

In one embodiment of the invention, the formation of the ion-implantation mask comprises the steps of: forming a pad oxide layer overlaying the semiconductor substrate; depositing a silicon nitride layer on the pad oxide layer; forming a photoresist pattern having a opening on the silicon nitride layer; etching the silicon nitride layer through the opening to create a silicon nitride mask; and removing the photoresist pattern to leave the silicon nitride mask.

In another embodiment of the invention, a silicon nitride spacer is preferably formed surrounding the sidewall of the silicon nitride mask by the conventional technique (deposition of silicon nitride layer followed by etching back the silicon nitride layer to form a silicon nitride spacer) According to this embodiment of the invention, the implantation-induced isolation can be easily shrunk to a desirable dimension.

In one embodiment of the invention, the implanting step can be a three-stage step respectively using energy of (i) 10˜40 keV, (ii) 50˜100 keV, and (iii) 100˜500 keV to achieve a dopant dosage of 1×10¹⁶˜1×10¹⁸ ions/cm² so that the oxygen ions in the oxygen doping region are more homogeneous or uniform. Alternately, the implanting step can be a multi-angle step to control the implanting direction of the oxide ions.

The thermal annealing is preferably carried out while an inert gas, such as nitrogen gas or argon gas is introduced into the oxidation chamber. Moreover, in the method the semiconductor substrate can be a silicon substrate.

In the other embodiment of the invention, nitrogen ions can be used to replace oxygen ions. Therefore, the implantation-induced isolation can be silicon nitride.

### BRIEF DESCRIPTION OF THE DRAWINGS

The preferred embodiment of the invention is hereinafter described with reference to the accompanying drawings in which:

FIGS. 1A to 1C are cross-sections showing the manufacturing steps of an implantation-induced isolation in a semiconductor substrate, in accordance with the first embodiment of the invention;

FIGS. 2A to 2C are cross-sections showing the manufacturing steps of an implantation-induced isolation in a semiconductor substrate, in accordance with the second embodiment of the invention; and

FIGS. 3A to 3C are cross-sections showing the manufacturing steps of an implantation-induced isolation in a semiconductor substrate, in accordance with the third embodiment of the invention.

### DETAILED DESCRIPTION OF THE PREFERRED EMBODIMENTS

[First Embodiment]

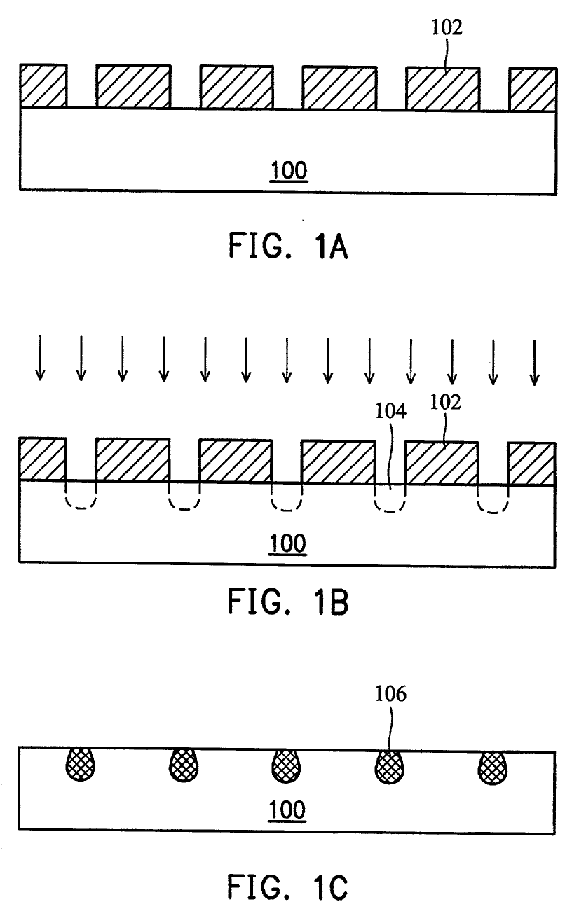

FIG. 1A to FIG. 1C are cross-sections showing the manufacturing steps of an implantation-induced isolation, according to the first embodiment of the invention.

As shown in FIG. 1A, a semiconductor substrate 100 made of single-crystalline silicon is provided. Next, a photoresist pattern 102 having openings is formed on the semiconductor substrate 100 to cover the active region by conventional photolithography comprising photoresist coating, photoresist exposing, and developing.

As shown in FIG. 1B, the photoresist pattern 102 is then used to serve as the implantation mask in order to implant oxygen ions into the semiconductor substrate 100 to form an oxygen doping region 104 where the implantation-induced isolation will form. The implanting step preferably includes three stages using energy of (i) 10˜40 keV, (ii) 50˜100 keV, and (iii) 100˜500 keV to implant oxygen ions into the predetermined depth throughout the semiconductor substrate 100 to achieve a dopant dosage of 1×10¹⁶˜1×10¹⁸ ions/cm². As a result, the oxygen ions in the oxygen doping region 104 are more homogeneous or uniform. Alternatively, to broaden the oxygen doping region 104, a multiple-stage implanting step using multiple angles can be used.

Next, referring to FIG. 1C, the photoresist pattern 102 is stripped. A thermal annealing is then utilized so that an isolating (silicon oxide) structure 106 serving as the implantation-induced isolation is generated by reaction of the oxygen ions in the oxygen doping region 104 with silicon. Moreover, to suppress undesirable oxidation, an inert gas such as nitrogen gas is introduced into the annealing furnace or the oxidation chamber for oxidation of implantation-induced isolation in this step.

[Second Embodiment]

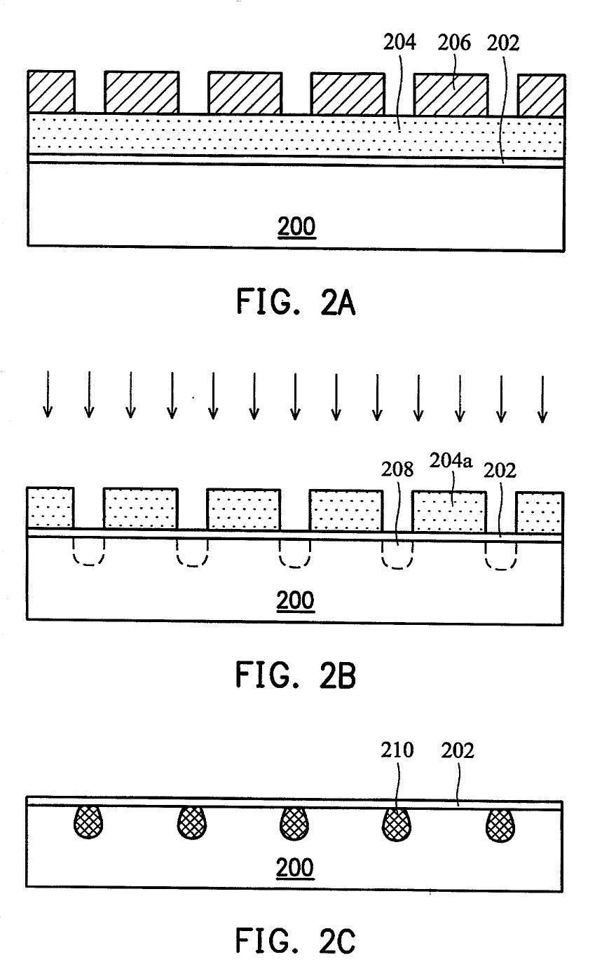

FIG. 2A to FIG. 2C are cross-sections showing the manufacturing steps of an implantation-induced isolation, according to the second embodiment of the invention.

As shown in FIG. 2A, a semiconductor substrate 200 made of single-crystalline silicon is provided. A pad oxide film 202 capable of enhancing adhesion between the silicon substrate 200 and the subsequent silicon nitride layer is formed overlaying the semiconductor substrate 200 by thermal oxidation or chemical vapor deposition (CVD) . A silicon nitride layer 204 is then deposited on the pad oxide film 202 by, for example, low pressure chemical vapor deposition (LPCVD). Afterward, a photoresist pattern 206 having openings is defined on the silicon nitride layer 204 by the convention photolithography comprising photoresist coating, photoresist exposing, and developing.

As shown in FIG. 2B, the silicon nitride layer 204 is then etched through the openings of the photoresist pattern 206 to expose the pad oxide film 202 and leave a silicon nitride mask 204a by reactive ion etching (RIE). During this step, the photoresist pattern 206 is used to serve as the etching mask. The photoresist pattern 206 is stripped by conventional skill. Next, the silicon nitride mask 204a is used to serve as the implantation mask in order to implant oxygen ions into the semiconductor substrate 200 to form an oxygen doping region 208 where the implantation-induced isolation will form. The implanting step preferably includes three stages using energy of (i) 10˜40 keV, (ii) 50˜100 keV, and (iii) 100˜500 keV to implant oxygen ions into the predetermined depth throughout the semiconductor substrate 200 to achieve a dopant dosage of 1×10¹⁶˜1×10¹⁸ ions/cm². As a result, the oxygen ions in the oxygen doping region 208 are more homogeneous or uniform. Alternatively, to broaden the oxygen doping region 208, a multiple-stage implanting step using multiple angles can be used.

Next, referring to FIG. 2C, the silicon nitride mask 204a is removed by a diluted phosphorus acid solution. A thermal annealing is utilized so that an isolating (silicon oxide) structure 210 serving as the implantation-induced isolation is generated by reaction of the oxygen ions in the oxygen doping region 208 with silicon. Moreover, to suppress undesirable oxidation, an inert gas such as nitrogen gas is introduced into the annealing furnace or the oxidation chamber for oxidation of implantation-induced isolation in this step.

[Third Embodiment]

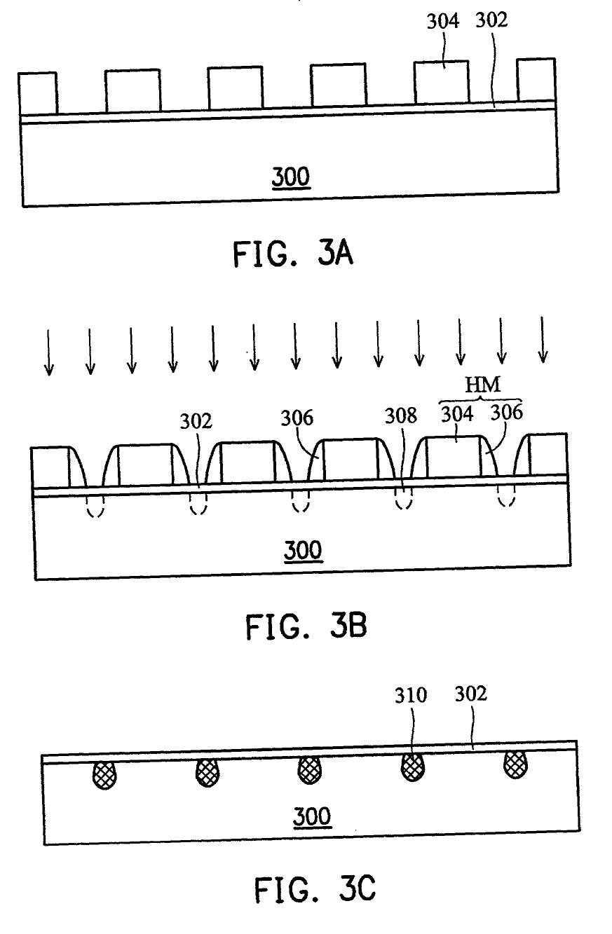

FIG. 3A to FIG. 3C are cross-sections showing the manufacturing steps of an implantation-induced isolation, according to the third embodiment of the invention. As shown in FIG. 3A, a semiconductor substrate 300 made of single-crystalline silicon is provided. A pad oxide film 302 capable of enhancing adhesion between the silicon substrate 300 and the subsequent silicon nitride is formed overlaying the semiconductor substrate 300 by thermal oxidation or chemical vapor deposition (CVD). A silicon nitride layer is then deposited on the pad oxide film 302 by low pressure chemical vapor deposition (LPCVD). Afterward, a photoresist pattern (not shown) having openings is defined on the silicon nitride layer by the convention photolithography comprising photoresist coating, photoresist exposing, and developing. the silicon nitride layer is then etched through the openings to create a silicon nitride mask 304.

As shown in FIG. 3B, a silicon nitride spacer 306 is formed surrounding the sidewall of the silicon nitride mask 304 by the conventional skill comprising silicon nitride deposition and etching back of silicon nitride. Accordingly, an implanting hard mask HM comprising the silicon nitride mask 304 and the silicon nitride spacer 306 is generated to shrink the ion-implanting pathway in order to achieve a narrower implantation-induced isolation. Next, the hard mask HM is used to serve as the implantation mask in order to implant oxygen ions into the semiconductor substrate 300 to form an oxygen doping region 308 where the implantation-induced isolation will form. The implanting step preferably includes three stages using energy of (i) 10˜40 keV, (ii) 50˜100 keV, and (iii) 100˜500 keV to implant oxygen ions into the predetermined depth throughout the semiconductor substrate 300 to achieve a dopant dosage of 1×10¹⁶˜1×10¹⁸ ions/cm². As a result, the oxygen ions in the oxygen doping region 308 are more homogeneous or uniform. Alternatively, to broaden the oxygen doping region 308, a multiple-stage implanting step using multiple angles can be used.

Next, referring to FIG. 3C, the silicon nitride mask HM is removed by a diluted phosphorus acid solution. A thermal annealing is then utilized so that an isolating (silicon oxide) structure 310 serving as the implantation-induced isolation is generated by reaction of the oxygen ions in the oxygen doping region 308 with silicon. Moreover, to suppress undesirable oxidation, an inert gas such as nitrogen gas is introduced into the annealing furnace or the oxidation chamber for oxidation of implantation-induced isolation in this step.

While the invention has been described with reference to various illustrative embodiments, the description is not intended to be construed in a limiting sense. Various modifications of the illustrative embodiments, as well as other embodiments of the invention, will be apparent to those person skilled in the art upon reference to this description. It is therefore contemplated that the appended claims will cover any such modifications or embodiments as may fall within the scope of the invention defined by the following claims and their equivalents.

What is claimed is:

1. A method of forming an implantation-induced isolation in a semiconductor substrate, comprising the steps of:
forming an ion-implantation mask on the semiconductor substrate to cover the active region;
implanting oxygen ions into the semiconductor substrate to form an oxygen doping region for formation of the implantation-induced isolation; and
annealing to generate an isolating structure serving as the implantation-induced isolation by reaction of the oxygen ions in the oxygen doping region with the component of the semiconductor substrate.

2. A method of forming an implantation-induced isolation as claimed in claim 1, wherein the ion-implantation mask is a photoresist pattern defined by photolithography.

3. A method of forming an implantation-induced isolation as claimed in claim 1, wherein the formation of ion-implantation mask comprises the steps of:
forming a pad oxide layer overlaying the semiconductor substrate;
depositing a silicon nitride layer on the pad oxide layer;
forming a photoresist pattern having a opening on the silicon nitride layer;
etching the silicon nitride layer through the opening to create a silicon nitride mask; and
removing the photoresist pattern to leave the silicon nitride mask.

4. A method of forming an implantation-induced isolation as claimed in claim 3, further comprising the step of forming a silicon nitride spacer surrounding the sidewall of the silicon nitride mask.

5. A method of forming an implantation-induced isolation as claimed in claim 1, wherein the step of implanting is a multiple-stage implanting step.

6. A method of forming an implantation-induced isolation as claimed in claim 5, wherein the multiple-stage implanting step is a three-stage step respectively using energy of (i) 10˜40 keV, (ii) 50˜100 keV, and (iii) 100˜500 keV to achieve a dopant dosage of 1×10¹⁶˜1×10¹⁸ ions/cm² so that the oxygen ions in the oxygen doping region are uniform.

7. A method of forming an implantation-induced isolation as claimed in claim 1, wherein the step of implanting is a multiple-angle implanting step so that the oxygen ions in the oxygen doping region are uniform.

8. A method of forming an implantation-induced isolation as claimed in claim 1, wherein the step of annealing is carried out while nitrogen gas is introduced.

9. A method of forming an implantation-induced isolation as claimed in claim 1, wherein the step of annealing is carried out while argon gas is introduced.

10. A method of forming an implantation-induced isolation as claimed in claim 1, wherein the semiconductor substrate is silicon substrate.

11. A method of forming an implantation-induced isolation in a semiconductor substrate, comprising a step of:
forming an ion-implantation mask on the semiconductor substrate to cover the active region;
implanting nitrogen ions into the semiconductor substrate to form an nitrogen doping region for formation of the implantation-induced isolation; and
annealing to generate an isolating structure serving as the implantation-induced isolation by reaction of the nitrogen ion in the nitrogen doping region with the component of the semiconductor substrate.

12. A method of forming an implantation-induced isolation as claimed in claim 11, wherein the ion-implantation mask is a photoresist pattern defined by photolithography.

13. A method of forming an implantation-induced isolation as claimed in claim 11, wherein the formation of ion-implantation mask comprising the steps of:
forming a pad oxide layer overlaying the semiconductor substrate;
depositing a silicon nitride layer on the pad oxide layer;
forming a photoresist pattern having a opening on the silicon nitride layer;
etching the silicon nitride layer through the opening to create a silicon nitride mask; and
removing the photoresist pattern to leave the silicon nitride mask.

14. A method of forming an implantation-induced isolation as claimed in claim 13, further comprising the step of forming a silicon nitride spacer surrounding the sidewall of the silicon nitride mask.

15. A method of forming an implantation-induced isolation as claimed in claim 11, wherein the step of implanting is a multiple-stage implanting step.

16. A method of forming an implantation-induced isolation as claimed in claim 15, wherein the multiple-stage implanting step is a three-stage step respectively using energy of (i) 10˜40 keV, (ii) 50˜φkeV, and (iii) 100˜500 keV to achieve a dopant dosage of 1×10¹⁶˜1×10¹⁸ ions/cm² so that the nitrogen ions in the nitrogen doping region are uniform.

17. A method of forming an implantation-induced isolation as claimed in claim 11, wherein the step of implanting is a multiple-angle implanting step so that the nitrogen ions in the nitrogen doping region are uniform.

18. A method of forming an implantation-induced isolation as claimed in claim 11, wherein the step of annealing is carried out while nitrogen gas is introduced.

19. A method of forming an implantation-induced isolation as claimed in claim 11, wherein the step of annealing is carried out while argon gas is introduced.
